(19) United States
(12) Patent Application Publication
(10) Pub. No.: US 2011/0240112 A1
(43) Pub. Date: Oct. 6, 2011

(54) FLEXIBLE DYE-SENSITIZED SOLAR CELL AND PREPARATION METHOD THEREOF

(75) Inventors: SUNG-HOON AHN, Seongnam-Si (KR); DOO-MAN CHUN, Seoul (KR); MIN-SAENG KIM, Seoul (KR)

(73) Assignee: SEOUL NATIONAL UNIVERSITY R&DB FOUNDATION, Seoul (KR)

(21) Appl. No.: 12/896,975

(22) Filed: Oct. 4, 2010

(30) Foreign Application Priority Data
Apr. 6, 2010 (KR) 10-2010-0031548

(51) Int. Cl. H01L 31/0224; H01L 31/18

(52) U.S. Cl. 136/256; 438/85; 257/E31.015; 257/E31.126

(57) ABSTRACT

Provided are a flexible dye-sensitized solar cell and a method for producing the same. More particularly, provided is a method for producing a flexible dye-sensitized solar cell, including: (Step 1) disposing a flexible polymer substrate having a transparent conductive oxide layer deposited thereon in a chamber; (Step 2) spraying oxide semiconductor powder with a size of 1 nm-10 μm carried by a gas onto the flexible polymer substrate having a transparent conductive oxide layer deposited thereon, at a velocity of 100-1200 m/sec by using a spray nozzle, to deposit an oxide semiconductor layer; (Step 3) allowing a dye to be adsorbed onto the oxide semiconductor layer to provide a working electrode; (Step 4) forming a catalyst layer on the top of a transparent substrate having a transparent conductive oxide layer thereon to provide a counter electrode; and (Step 5) allowing the working electrode obtained from Step 3 and the counter electrode obtained from Step 4 to face each other, laminating the two electrodes with each other, and injecting an electrolyte. A flexible dye-sensitized solar cell obtained by the method is also provided.

### CROSS-REFERENCE TO RELATED APPLICATION

This application claims priority under 35 U.S.C. §119 the benefit of Korean Patent Application No. 10-2010-0031548, filed on Apr. 6, 2010, the entire contents of which are incorporated herein by reference.

### BACKGROUND OF THE INVENTION

(a) Field of the Invention

The present invention relates to a method for producing a flexible dye-sensitized solar cell using a low-temperature deposition process that causes no damages on a flexible polymer substrate during the deposition of an oxide semiconductor layer in fabricating a working electrode and a counter electrode, as well as to a flexible dye-sensitized solar cell obtained by the same method.

(b) Description of the Related Art

Recently, research and development into next-generation clean energy sources have been spotlighted due to severe environmental pollution problems and depletion of fossil energy sources. Among such clean energy sources, solar cells converting solar energy directly into electric energy are expected to be one of the most important candidates capable of solving the future energy problems, since they cause little pollution, they are inexhaustible sources, and they have semi-permanent life.

Such solar cells may be classified broadly, depending on key materials used therein, into inorganic solar cells, dye-sensitized solar cells and organic solar cells.

As inorganic solar cells, single crystal silicon solar cells are used widely. Such single crystal silicon-based solar cells are advantageous in that they are produced in the form of thin film type solar cells. However, they are not cost efficient and they have poor stability.

Unlike conventional silicon solar cells based on p-n bonding, dye-sensitized solar cells are optoelectrochemical solar cells that include, as main ingredients, a photosensitive dye molecule capable of absorbing visible light to generate electron-hole pairs, and a transition metal oxide transporting the thus generated electrons. As compared to conventional silicon-based solar cells, such dye-sensitized solar cells can resist exposure to light and heat for a longer time, and produce energy with ease in a cost efficient manner.

Typical examples of dye-sensitized solar cells known to date include a solar cell disclosed in U.S. Pat. Nos. 4,927,721 and 5,350,644 by Gratzel et al. (Switzerland). The dye-sensitized solar cell suggested by Gratzel et al. includes: a semiconductor electrode containing titanium dioxide (TiO₂) nanoparticles coated with dye molecules; a counter electrode coated with platinum or carbon; and an electrolyte solution filled in the gap between the two electrodes. Such an optoelectrochemical solar cell is highly advantageous in that it is produced at low cost versus electric power, as compared to conventional silicon-based solar cells. The technological gist developed by Gratzel et al. demonstrates that the dye-sensitized solar cell may be a cost-efficient substitute for an expensive silicon-based solar cell.

More recently, a lot of attention has been given to flexible dye-sensitized solar cells using flexible semiconductor electrodes, since such flexible dye-sensitized solar cells can be applied to self-charging of power required for mobile phones or advanced personal computers, such as wearable personal computers, etc., and can be attached to clothes, caps or hats, glass windows of cars, buildings, or the like.

However, some flexible substrates required for fabricating such flexible semiconductor electrodes undergo deformation with ease at high temperature. Thus, when forming an oxide semiconductor layer, such as a titanium dioxide layer, a high-temperature deposition process cannot be used, and the semiconductor electrodes should be fabricated at a low temperature of 150° C. or less.

Known methods for fabricating flexible semiconductor electrodes include printing a low-temperature fired paste onto a flexible substrate, followed by drying at a temperature of 100° C. or less, or forming a semiconductor layer on opaque metal foil. However, the above methods cause degradation of optoelectrical efficiency or film stability. Therefore, there has been a continuous need for a novel method for fabricating a flexible semiconductor electrode stably at low temperature.

To solve the above-mentioned problems, we have conducted many studies to develop a method for fabricating a working electrode and a counter electrode by using a flexible polymer substrate. Finally, we have found that when an oxide semiconductor layer is deposited on a flexible polymer substrate by a low-temperature deposition process to provide a working electrode and a counter electrode using a flexible polymer substrate, it is possible to prevent damages on a flexible polymer substrate having low temperature resistance. Based on this finding, a method for producing a flexible dye-sensitized solar cell, and a flexible dye-sensitized solar cell obtained thereby are provided.

### SUMMARY OF THE INVENTION

An object of the present invention is to provide a method for producing a flexible dye-sensitized solar cell, including a simplified process wherein an oxide semiconductor layer is deposited at low temperature to provide a working electrode and a counter electrode using a flexible polymer substrate having low temperature resistance, as well as a flexible dye-sensitized solar cell obtained by the same.

In one general aspect, there is provided a method for producing a flexible dye-sensitized solar cell, including:

(Step 1) disposing a flexible polymer substrate having a transparent conductive oxide layer deposited thereon in a chamber;

(Step 2) spraying oxide semiconductor powder with a size of 1 nm-10 μm carried by a gas onto the flexible polymer substrate having a transparent conductive oxide layer deposited thereon, at a velocity of 100-1200 m/sec by using a spray nozzle, to deposit an oxide semiconductor layer;

(Step 3) allowing a dye to be adsorbed onto the oxide semiconductor layer to provide a working electrode;

(Step 4) forming a catalyst layer on the top of a transparent substrate having a transparent conductive oxide layer thereon to provide a counter electrode; and

(Step 5) allowing the working electrode obtained from Step 3 and the counter electrode obtained from Step 4 to face each other, laminating the two electrodes with each other, and injecting an electrolyte.

In another general aspect, there is provided a flexible dye-sensitized solar cell, including: a working electrode including a transparent conductive oxide layer deposited on a flexible polymer substrate, an oxide semiconductor layer deposited on the transparent conductive oxide layer at low temperature, and a dye adsorbed on the oxide semiconductor layer; a counter electrode including a transparent conductive oxide layer deposited on a flexible polymer substrate and a catalyst layer deposited on the transparent conductive oxide layer at a low temperature of 150° C. or less; and an electrolyte interposed between the working electrode and the counter electrode.

According to a particular embodiment of the present invention, the working electrode may be obtained by the method including: disposing a flexible polymer substrate having a transparent conductive oxide layer deposited thereon in a substrate-supporting section of a chamber at room temperature under vacuum; and spraying oxide semiconductor powder with a size of 1 nm-10 μm carried by a gas onto the substrate, at a velocity of 100-1200 m/sec by using a spray nozzle to form an oxide semiconductor layer, and then allowing a dye to be adsorbed onto the oxide semiconductor layer.

According to another embodiment, the oxide semiconductor powder may be selected from the group consisting of titanium dioxide (TiO₂) powder, tin oxide (SnO₂) powder, zinc oxide (ZnO) powder, niobium oxide powder (Nb₂O₅) and a combination thereof; or may include a mixture containing at least one selected from the group consisting of titanium dioxide (TiO₂) powder, tin oxide (SnO₂) powder, zinc oxide (ZnO) powder and niobium oxide (Nb₂O₅) powder, and at least one selected from the group consisting of carbon nanotubes (CNT), carbon nanofibers (CNF) and graphene.

According to still another embodiment, the flexible polymer substrate may be prepared by using a polymer selected from the group consisting of polyethylene terephthalate (PET), polyethylene naphthalate (PEN), polyethylene (PE), polyethersulfone (PES), polycarbonate (PC), polyarylate (PAR), polyimide (PI), etc.

According to yet another embodiment, the transparent conductive oxide layer may be formed from a transparent conductive oxide selected from the group consisting of fluorine-doped tin oxide (FTO), indium tin oxide (ITO), indium zinc oxide (IZO), indium zinc tin oxide (IZTO), aluminum zinc oxide (AZO), indium tin oxide-silver-indium tin oxide (ITO-Ag-ITO), indium zinc oxide-silver-indium zinc oxide (ITO-Ag-IZO), indium zinc tin oxide-silver-indium zinc tin oxide (IZTO-Ag-IZTO), aluminum zinc oxide-silver-aluminum zinc oxide (AZO-Ag-AZO), or the like.

The present invention provides a method for producing a flexible dye-sensitized solar cell, including a simplified process wherein an oxide semiconductor layer is deposited to a flexible polymer substrate at low temperature to provide a working electrode and a counter electrode using a flexible polymer substrate, as well as a flexible dye-sensitized solar cell obtained by the same.

### BRIEF DESCRIPTION OF THE DRAWINGS

Description will now be given in detail with reference to certain example embodiments illustrated in the accompanying drawings which are given hereinafter by way of illustration only, and thus are not limitative of the present invention, and wherein:

FIG. 1 is a lateral sectional view of a working electrode obtained in accordance with a particular embodiment of the present invention;

FIG. 2 is a lateral sectional view of a flexible dye-sensitized solar cell obtained in accordance with a particular embodiment of the present invention; and

FIG. 3 is a schematic view showing the construction of a flexible display based on a flexible dye-sensitized solar cell.

It should be understood that the appended drawings are not necessarily to scale, presenting a somewhat simplified representation of various preferred features illustrative of the basic principles. The specific design features as disclosed herein, including, for example, specific dimensions, orientations, locations and shapes will be determined in part by the particular intended application and use environment.

In the figures, reference numerals refer to the same or equivalent parts throughout the figures of the drawing.

### DETAILED DESCRIPTION OF THE PREFERRED EMBODIMENTS

Hereinafter, reference will now be made in detail to various embodiments, examples of which are illustrated in the accompanying drawings and described below. While the invention will be described in conjunction with example embodiments, it will be understood that the present description is not intended to limit to those example embodiments.

In one aspect, there is provided a method for producing a flexible dye-sensitized solar cell, including:

(Step 1) disposing a flexible polymer substrate having a transparent conductive oxide layer deposited thereon in a chamber;

(Step 2) spraying oxide semiconductor powder with a size of 1 nm-10 μm carried by a gas onto the flexible polymer substrate having a transparent conductive oxide layer deposited thereon, at a velocity of 100-1200 m/sec by using a spray nozzle, to deposit an oxide semiconductor layer;

(Step 3) allowing a dye to be adsorbed onto the oxide semiconductor layer to provide a working electrode;

(Step 4) forming a catalyst layer on the top of a transparent substrate having a transparent conductive oxide layer thereon to provide a counter electrode; and

(Step 5) allowing the working electrode obtained from Step 3 and the counter electrode obtained from Step 4 to face each other, laminating the two electrodes with each other, and injecting an electrolyte.

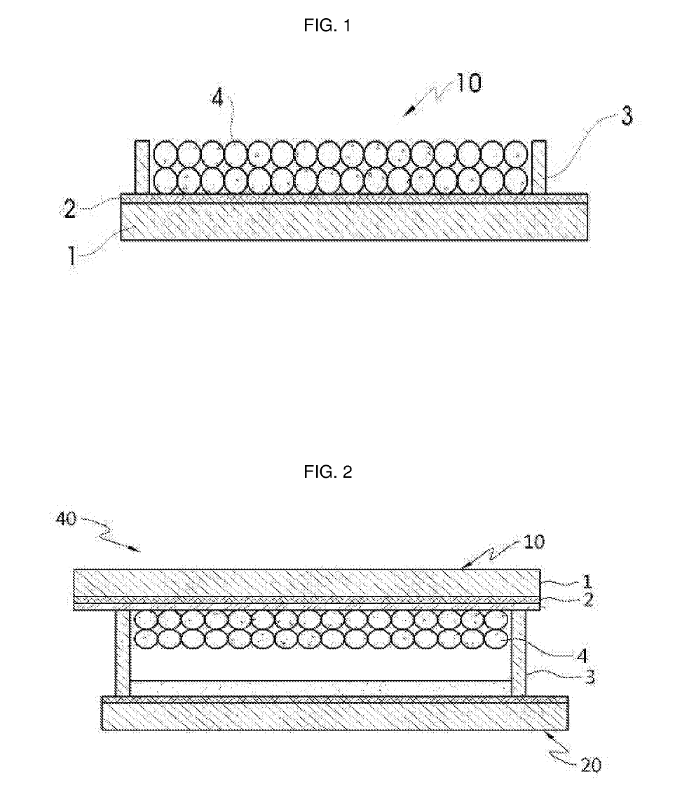

Hereinafter, the method for producing a flexible dye-sensitized solar cell will be described in detail with reference to FIG. 1 and FIG. 2.

FIG. 1 is a lateral sectional view of a working electrode 10 obtained in accordance with a particular embodiment of the present invention.

First, a flexible polymer substrate 1 having a transparent conductive oxide layer 2 deposited thereon is disposed in a substrate-supporting section within a chamber (Step 1).

In Step 1, the chamber, in which application of the oxide semiconductor layer 4 is carried out, is maintained preferably at room temperature under vacuum or atmospheric pressure, and more preferably, under vacuum. When the chamber is maintained under vacuum, it is possible to reduce the flow resistance in carrying titanium dioxide powder forming the oxide semiconductor layer 4 by a gas, and thus to avoid any factor causing a drop in powder velocity. In this manner, it is possible to facilitate forming the oxide semiconductor layer 4.

Next, oxide semiconductor powder with a size of 1 nm-10 μm carried by a gas is sprayed onto the flexible polymer substrate 1 having a transparent conductive oxide layer 2 deposited thereon, at a velocity of 100-1200 m/sec by using a spray nozzle, to deposit an oxide semiconductor layer 4 (Step 2).

Particular examples of the materials forming the flexible polymer substrate used herein include but are not limited to polyethylene terephthalate (PET), polyethylene naphthalate (PEN), polyethylene (PE), polyethersulfone (PES), polycarbonate (PC), polyarylate (PAR), polyimide (PI), etc.

The transparent conductive oxide layer 2 is formed on the top of the flexible polymer substrate 1, and particular examples of the materials forming the transparent conductive oxide layer 2 include but are not limited to fluorine-doped tin oxide (FTO), indium tin oxide (ITO), indium zinc oxide (IZO), indium zinc tin oxide (IZTO), aluminum zinc oxide (AZO), indium tin oxide-silver-indium tin oxide (ITO-Ag-ITO), indium zinc oxide-silver-indium zinc oxide (ITO-Ag-IZO), indium zinc tin oxide-silver-indium zinc tin oxide (IZTO-Ag-IZTO), aluminum zinc oxide-silver-aluminum zinc oxide (AZO-Ag-AZO), or the like.

When the oxide semiconductor layer 4 is formed on the flexible polymer substrate 1, having a transparent conductive oxide layer 2 deposited thereon, in Step 2, fine powder of oxide semiconductor with a size of 1 nm-10 μm is sprayed at a relatively high spraying velocity of 100-1200 m/sec. In this manner, it is possible to minimize the effect of the oxide semiconductor powder colliding with the substrate upon the substrate. The oxide semiconductor powder may be coated on the substrate while the powder collides with the substrate so that it is broken and reunited. To obtain such a high spraying velocity of oxide semiconductor powder, pressurized air with a pressure of 1-10 bar is used generally and a vacuum range of 10 torr-760 torr may be used.

The oxide semiconductor powder may be at least one powder selected from the group consisting of titanium dioxide (TiO₂) powder, tin oxide (SnO₂) powder, zinc oxide (ZnO) powder, niobium oxide powder (Nb₂O₅) and a combination thereof.

In a particular embodiment, in order to increase the optoelectric conversion efficiency, transmission, resistance, etc. of a flexible dye-sensitized solar cell, the oxide semiconductor powder used for forming the oxide semiconductor layer 4 may include a mixture containing at least one selected from the group consisting of titanium dioxide (TiO₂) powder, tin oxide (SnO₂) powder, zinc oxide (ZnO) powder and niobium oxide (Nb₂O₅) powder, and at least one selected from the group consisting of carbon nanotubes (CNT), carbon nanofibers (CNF) and graphene.

In another particular embodiment, after the oxide semiconductor layer 4 is formed on the flexible polymer substrate 1 having a transparent conductive oxide layer 2 deposited thereon, the method may further include pressurizing the oxide semiconductor layer by a press, etc.; subjecting the oxide semiconductor layer to a low-temperature sintering process by using a vacuum low-temperature sintering furnace or oven at a temperature lower than the glass transition temperature of the flexible polymer substrate; or sintering the deposited transparent conductive oxide layer locally by laser.

After forming the oxide semiconductor layer 4 in Step 2, a dye is allowed to be adsorbed onto the oxide semiconductor layer to provide a working electrode 10 (Step 3).

In a particular embodiment, adsorption of the dye onto the oxide semiconductor layer 4 deposited on the flexible polymer substrate 1 may be carried out by dipping the flexible polymer substrate 1 having the oxide semiconductor layer 4 into a dye solution.

The dye solution may include a mixture containing a dye and an alcohol solution. The dyes that may be used herein include materials containing a ruthenium (Ru) complex and capable of absorbing visible light. In addition to such dyes, it is possible to use a dye capable of improving absorption in a long wavelength range within visible light to improve the absorption efficiency, and a novel type of dye capable of facilitating release of electrons.

Then, a catalyst layer is formed on the top of a flexible polymer substrate having a transparent conductive oxide layer to provide a counter electrode (Step 4).

In a similar manner to Step 2, a transparent conductive oxide layer is formed on the top of the flexible polymer substrate, and then a catalyst layer is deposited thereon to provide a counter electrode 20.

The catalyst layer may be formed of carbon, gold, platinum, or the like, a noble metal, such as platinum (Pt) being preferred. Since platinum (Pt) has high reflectance, the visible light transmitted through the catalyst layer may be reflected toward the inside of a solar cell, resulting in improvement of light absorption efficiency. In addition to platinum (Pt), other noble metals having a low resistance value may also be used.

Finally, the working electrode obtained from Step 3 and the counter electrode obtained from Step 4 are allowed to face each other, and an electrolyte is injected between the two electrodes (Step 5).

FIG. 2 is a lateral sectional view of a flexible dye-sensitized solar cell 40 obtained in accordance with a particular embodiment of the present invention.

Referring to FIG. 2, in Step 5, the working electrode 10 obtained from Step 3 and the counter electrode 20 obtained from Step 4 are laminated with each other, and then an electrolyte is injected into the laminate to provide a flexible dye-sensitized solar cell 40.

The electrolyte used in the flexible dye-sensitized solar cell 40 may be any liquid electrolyte or solid polymer electrolyte generally known to those skilled in the art.

When producing a flexible dye-sensitized solar cell according to the method for producing a flexible dye-sensitized solar cell as described above, it is possible to obtain a flexible dye-sensitized solar cell in a simple manner by depositing an oxide semiconductor layer at low temperature, while not adversely affecting a flexible polymer substrate having low temperature resistance.

In addition, one of the working electrode and the counter electrode used in the above-described flexible dye-sensitized solar cell and the method for producing the same may be obtained by using a glass substrate or metal substrate, besides a flexible polymer substrate.

In another aspect, there is provided a flexible dye-sensitized solar cell, including: a working electrode including a transparent conductive oxide layer deposited on a flexible polymer substrate, a nano-oxide layer deposited on the transparent conductive oxide layer, and a dye adsorbed on the nano-oxide layer; a counter electrode including a transparent conductive oxide layer deposited on a flexible polymer substrate and a catalyst layer deposited on the transparent conductive oxide layer at low temperature; and an electrolyte interposed between the working electrode and the counter electrode.

The flexible dye-sensitized solar cell may be obtained by the above-described method according to the present invention.

In still another aspect, there is provided a flexible display based on a flexible dye-sensitized solar cell including the above-described dye-sensitized solar cell according to the present invention.

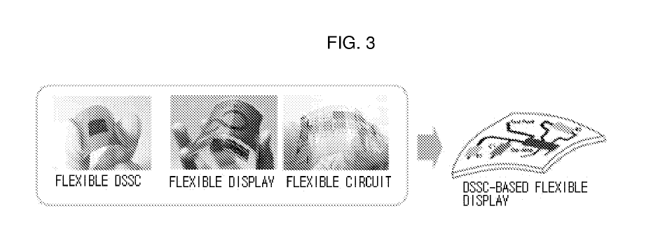

FIG. 3 is a schematic view showing the construction of a flexible display based on a flexible dye-sensitized solar cell. As shown in FIG. 3, there is provided a DSSC (dye-sensitized solar cell)-based flexible display including a combination of a flexible display, a flexible circuit and the flexible dye-sensitized solar cell according to the present invention.

The present invention is further explained in more detail with reference to the following examples. These examples, however, should not be interpreted as limiting the scope of the present invention in any manner.

### EXAMPLE 1

(1) Fabrication of Working Electrode

A PET (polyethylene terephthalate) substrate having an indium tin oxide transparent conductive oxide layer is provided and disposed in a substrate-supporting section of a vacuum chamber. Titanium dioxide powder with a size of 10 nm is sprayed onto the PET substrate at a velocity of 300-500 m/sec to form a nano-oxide layer with a thickness of 5 μm. Then, 5 mM rubidium (Ru)-based dye (Solaronix Co., Ruthenium 535-bis TBA) dissolved in ethanol as a solvent is prepared. The substrate having a nano-oxide layer is dipped in the dye for 24 hours and dried to provide a working electrode on which a dye is adsorbed.

(2) Fabrication of Counter Electrode

A PET substrate having a fluorine-doped tin oxide transparent conductive oxide layer is provided. A deposition system including a platinum target is used and a current of 15 mA is maintained under vacuum of 10⁻¹ torr or less for 200 seconds to form a platinum layer within the edge of the substrate, thereby providing a counter electrode.

(3) Production of Flexible Dye-Sensitized Solar Cell

The working electrode and the counter electrode are positioned in such a manner that the nano-oxide layer of the working electrode faces the platinum layer of the counter electrode. Next, a double-sided adhesive tape (available from 3M Co.) with a thickness of 70 μm is used to laminate the two electrodes at the outer circumference of the nano-oxide layer. Then, a hot press is used under the conditions of 50° C./5 MPa for 10 seconds to laminate the two electrodes. Herein, the counter electrode is perforated preliminarily for the injection of an electrolyte. After that, approximately 0.1 cc of an electrolyte solution (Solaronix, lodolyte AN-50) is injected into the gap between the two electrodes through the preformed perforation, and then the perforation is sealed with an epoxy resin, thereby providing a flexible dye-sensitized solar cell.

### EXAMPLE 2

Example 1 is repeated to provide a flexible dye-sensitized solar cell, except that the working electrode is fabricated by spraying titanium dioxide powder with a size of 10 nm and multi-walled carbon nanotubes (Hanwha Nanotec, CM-95) at a velocity of 300-500 m/sec to form a nano-oxide layer with a thickness of 5 μm.

### TEST EXAMPLES

### TEST EXAMPLE 1

### Measurement of Current Density (J_{sc}) and Voltage (V_{oc})

The dye-sensitized solar cells obtained from Examples 1 and 2 are tested to measure the current density (J_{sc}), voltage (V_{oc}) and fill factor (ff) of each solar cell. The results are shown in the following Table 1.

TABLE 1

| | Current Density | Open Circuit | |
|---|---|---|---|
| | (mA/cm²) | Voltage (V) | Fill Factor |
| Example 1 | 0.474 | 0.7085 | 25.88 |
| Example 2 | 0.211 | 0.6393 | 38.89 |

Description was made in detail with reference to example embodiments. However, it will be appreciated by those skilled in the art that changes may be made in these embodiments without departing from the principles and spirit of the present invention, the scope of which is defined in the accompanying claims and their equivalents.

What is claimed is:

1. A flexible dye-sensitized solar cell, comprising:
a working electrode comprising a transparent conductive oxide layer deposited on a flexible polymer substrate, an oxide semiconductor layer deposited on the transparent conductive oxide layer at low temperature, and a dye adsorbed on the oxide semiconductor layer;
a counter electrode comprising a transparent conductive oxide layer deposited on a flexible polymer substrate and a catalyst layer deposited on the transparent conductive oxide layer at low temperature; and
an electrolyte interposed between the working electrode and the counter electrode,
wherein the oxide semiconductor layer deposited on the transparent conductive oxide layer is formed by spraying oxide semiconductor powder with a size of 1 nm-10 μm carried by a gas onto the substrate having a transparent conductive oxide layer deposited thereon, at a velocity of 100-1200 m/sec by using a spray nozzle at a low temperature of 150° C. or less.

2. The flexible dye-sensitized solar cell according to claim 1, wherein the oxide semiconductor powder is selected from the group consisting of titanium dioxide (TiO₂) powder, tin oxide (SnO₂) powder, zinc oxide (ZnO) powder, niobium oxide powder (Nb₂O₅) and a combination thereof; or comprises a mixture containing at least one selected from the group consisting of titanium dioxide (TiO₂) powder, tin oxide (SnO₂) powder, zinc oxide (ZnO) powder and niobium oxide (Nb₂O₅) powder, and at least one selected from the group consisting of carbon nanotubes (CNT), carbon nanofibers (CNF) and graphene.

3. The flexible dye-sensitized solar cell according to claim 1, wherein the flexible polymer substrate is prepared by using a polymer selected from the group consisting of polyethylene terephthalate (PET), polyethylene naphthalate (PEN), polyethylene (PE), polyethersulfone (PES), polycarbonate (PC), polyarylate (PAR), and polyimide (PI).

4. The flexible dye-sensitized solar cell according to claim 1, wherein the transparent conductive oxide layer is formed from a transparent conductive oxide selected from the group consisting of fluorine-doped tin oxide (FTO), indium tin oxide (ITO), indium zinc oxide (IZO), indium zinc tin oxide (IZTO), aluminum zinc oxide (AZO), indium tin oxide-silver-indium tin oxide (ITO-Ag-ITO), indium zinc oxide-silver-indium zinc oxide (ITO-Ag-IZO), indium zinc tin oxide-silver-indium zinc tin oxide (IZTO-Ag-IZTO), and aluminum zinc oxide-silver-aluminum zinc oxide (AZO-Ag-AZO).

5. The flexible dye-sensitized solar cell according to claim 1, wherein the catalyst layer is formed from a material selected from the group consisting of carbon, gold and platinum.

6. The flexible dye-sensitized solar cell according to claim 1, wherein one of the working electrode and the counter electrode is obtained by using a flexible glass substrate or metal substrate.

7. A method for producing a flexible dye-sensitized solar cell, comprising:
(Step 1) disposing a flexible polymer substrate having a transparent conductive oxide layer deposited thereon in a chamber;
(Step 2) spraying oxide semiconductor powder with a size of 1 nm-10 μm carried by a gas onto the flexible polymer substrate having a transparent conductive oxide layer deposited thereon, at a velocity of 100-1200 m/sec by using a spray nozzle at a low temperature of 150° C. or less, to deposit an oxide semiconductor layer;
(Step 3) allowing a dye to be adsorbed onto the oxide semiconductor layer to provide a working electrode;
(Step 4) forming a catalyst layer on the top of a transparent substrate having a transparent conductive oxide layer thereon to provide a counter electrode; and
(Step 5) allowing the working electrode obtained from Step 3 and the counter electrode obtained from Step 4 to face each other, laminating the two electrodes with each other, and injecting an electrolyte.

8. The method for producing a flexible dye-sensitized solar cell according to claim 7, wherein the oxide semiconductor powder is selected from the group consisting of titanium dioxide (TiO₂) powder, tin oxide (SnO₂) powder, zinc oxide (ZnO) powder, niobium oxide powder (Nb₂O₅) and a combination thereof; or comprises a mixture containing at least one selected from the group consisting of titanium dioxide (TiO₂) powder, tin oxide (SnO₂) powder, zinc oxide (ZnO) powder and niobium oxide (Nb₂O₅) powder, and at least one selected from the group consisting of carbon nanotubes (CNT), carbon nanofibers (CNF) and graphene.

9. The method for producing a flexible dye-sensitized solar cell according to claim 7, which further comprises, after forming the oxide semiconductor layer by spraying the oxide semiconductor powder, pressurizing the oxide semiconductor layer by a press; subjecting the oxide semiconductor layer to a low-temperature sintering process by using a vacuum low-temperature sintering furnace or oven at a temperature lower than the glass transition temperature of the flexible polymer substrate; or sintering the transparent conductive oxide layer locally by laser.

10. The method for producing a flexible dye-sensitized solar cell according to claim 7, wherein the flexible polymer substrate is prepared by using a polymer selected from the group consisting of polyethylene terephthalate (PET), polyethylene naphthalate (PEN), polyethylene (PE), polyethersulfone (PES), polycarbonate (PC), polyarylate (PAR), and polyimide (PI).

11. The method for producing a flexible dye-sensitized solar cell according to claim 7, wherein the transparent conductive oxide layer is formed from a transparent conductive oxide selected from the group consisting of fluorine-doped tin oxide (FTO), indium tin oxide (ITO), indium zinc oxide (IZO), indium zinc tin oxide (IZTO), aluminum zinc oxide (AZO), indium tin oxide-silver-indium tin oxide (ITO-Ag-ITO), indium zinc oxide-silver-indium zinc oxide (ITO-Ag-IZO), indium zinc tin oxide-silver-indium zinc tin oxide (IZTO-Ag-IZTO), and aluminum zinc oxide-silver-aluminum zinc oxide (AZO-Ag-AZO).

12. The method for producing a flexible dye-sensitized solar cell according to claim 7, wherein the catalyst layer is formed from a material selected from the group consisting of carbon, gold and platinum.

13. A flexible dye-sensitized solar cell-based display provided with a flexible dye-sensitized solar cell comprising:
a working electrode comprising a transparent conductive oxide layer deposited on a flexible polymer substrate, an oxide semiconductor layer deposited on the transparent conductive oxide layer at low temperature, and a dye adsorbed on the oxide semiconductor layer;
a counter electrode comprising a transparent conductive oxide layer deposited on a flexible polymer substrate and a catalyst layer deposited on the transparent conductive oxide layer at low temperature; and
an electrolyte interposed between the working electrode and the counter electrode,
wherein, the oxide semiconductor layer deposited on the transparent conductive oxide layer is formed by spraying oxide semiconductor powder with a size of 1 nm-10 μm carried by a gas onto the substrate having a transparent conductive oxide layer deposited thereon, at a velocity of 100-1200 m/sec by using a spray nozzle at a low temperature of 150° C. or less.

14. The flexible dye-sensitized solar cell-based display according to claim 13, wherein the oxide semiconductor powder is selected from the group consisting of titanium dioxide (TiO₂) powder, tin oxide (SnO₂) powder, zinc oxide (ZnO) powder, niobium oxide powder (Nb₂O₅) and a combination thereof; or comprises a mixture containing at least one selected from the group consisting of titanium dioxide (TiO₂) powder, tin oxide (SnO₂) powder, zinc oxide (ZnO) powder and niobium oxide (Nb₂O₅) powder, and at least one selected from the group consisting of carbon nanotubes (CNT), carbon nanofibers (CNF) and graphene.
